(19) United States
(12) Patent Application Publication
(10) Pub. No.: US 2008/0110489 A1
(43) Pub. Date: May 15, 2008

(54) Very High Efficiency Multi-Junction Solar Spectrum Integrator Cells, and the Corresponding System and Method

(76) Inventor: Fareed Sepehry-Fard, Saratoga, CA (US)

Correspondence Address: MAXVALUEIP CONSULTING, 11204 ALBERMYRTLE ROAD, POTOMAC, MD, 20854, US

(21) Appl. No.: 11/559,893

(22) Filed: Nov. 14, 2006

(51) Int. Cl. H01L 31/052; H01L 31/05

(52) U.S. Cl. 136/246

(57) ABSTRACT

Application of Solid Phase Epitaxy (SPE) fabrication technology to very high efficiency radiation hardened solar cells, and the corresponding system and method, are presented. The heteroepitaxial structure of ZnSe/GaAs/Ge is realizable, due to the adequate lattice matching of the component crystals. It offers several advantages compared to the other solar cell systems based on AlₓGa₁₋ₓAs/GaAs/Ge/Si type of heteroepitaxial photovoltaic solar energy converters. The active p-n junction is maintained in the well-known high power conversion efficiency of GaAs. ZnSe is a direct large band gap semiconductor. Therefore, the energy integration effect of the graded band structure of the type ZnₓGa_{y}Se₁₋ₓAs_{1-y}, created at the heteroepitaxial interface, is extended, with respect to the one present in the GaₓAl₁₋ₓAs system. This graded band gap phenomenon introduces a built-in potential, improving the capture efficiency of the GaAs p-n junction, placed to its close vicinity. Furthermore, the luminescence of ZnSe, acting as a frequency down conversion path, increases the spectral response of the solar cell system. Using germanium as an available large substrate material, the thin film ZnSe/GaAs/Ge heteroepitaxial structure could result in a much high power conversion efficiency, and a reduced cost for the solar energy converter.

### BACKGROUND

Here is the description of the prior art:

Simon Fafard (Patent Application No. 20050155641) teaches a solar cell with epitaxially-grown quantum dot material: A monolithic semiconductor photovoltaic solar cell comprising a plurality of subcells disposed in series on an electrically conductive substrate. At least one subcell of the plurality of subcells includes an epitaxially-grown self-assembled quantum dot material. The subcells are electrically connected via tunnel junctions. Each of the subcells has an effective band gap energy. The subcells are disposed in order of increasing effective ban gap energy, with the subcell having the lowest effective band gap energy being closest to the substrate. In certain cases, each subcell is designed to absorb a substantially same amount of solar photons.

Olson et al. (PN 5316593) teaches a heterojunction solar cell with passivated emitter surface. Olson (PN 4667059) teaches a current and lattice matched tandem solar cell. Olson et al. (PN 5223043) teaches current-matched high-efficiency multijunction monolithic solar cells.

Spectrolab (PN 6380601, PN 6150603, and PN 6255580) (spectrolab.com) teaches some improved/ultra triple junction solar cells.

A paper titled “Projected performance of three and four junction devices using GalnP and GaAs” by Sarah R. Kurtz, D Myers, and J. M. Olson, of National Renewable Energy, teaches solar cells.

US patent application 20060144435, by Mark W. Wanlass, filed Jul. 6, 2006, teaches multi-band gap photovoltaic converters.

Sepehry-Fard (the same inventor of the current application) (PN 5725659) teaches a solid phase epitaxy reactor, incorporated here by reference.

Other prior art are listed here for reference: (All of the teachings of the prior art by the same inventor/assignee of the current invention (F. Sepehry-Fard) are incorporated here by reference.)
1. F. Sepehry-Fard, “DLTS and Hall Effect Measurement of GaAs Solid Phase Epitaxy Technology for cost effective laser applications”, European Conference on Lasers and Electrooptics/Euoropean Quantum Electronics Conference, Amsterdam, Netherlands, Aug. 28 to Sep. 2, 1994.
2. F. Sepehry-Fard, “Solid Phase Epitaxy Technique. The most cost effective GaAs/InP technology for space applications”, Space cast 2020, a US Air Force study on Technology and Innovative Applications of space hardware, Wright. Patterson AFB, OH 45433-7765, June 1994.
3. F. Sepehry-Fard, “DLTS and Hall Effect Measurement of GaAs Solid Phase Epitaxy Technology for space applications”, Space cast 2020, a US Air Force study on Technology and Innovative Applications of space hardware, Wright Patterson AFB, OH 45433-7765, June 1994.
4. F. Sepehry-Fard, “Solid Phase Epitaxy processed Pseudomorphic High Electron Mobility Transistor (PHEMT) for wireless Applications’, The Can Am Microelectronics & Packaging, Granby, Quebec, Canada, Sep. 13 to Sep. 15, 1995.
5. F. Sepehry-Fard, “FSF's revolutionary GaAs Processing and Manufacturing Technology”, 1996 International Conference on Gallium Arsenide Manufacturing Technology, San Diego, Calif., USA, Apr. 28 to May 25, 1996.
6. F. Sepehry-Fard, “Epitaxial Process delivers high performance PHEMTS”, RF and Microwave Magazine, a Penton Publication, February 1996.
7. F. Sepehry-Fard, “Solid Phase Epitaxy Processed MMIC high power, high efficiency and low noise amplifier for local multi point distribution services (LMDS), and local multi-point communication systems (LMCS) applications”, published in Asia Pacific communications conference 98, (APCC 98).
8. F. Sepehry-Fard, “The design and fabrication of a novel ½ watt, n>52% Solid Phase Epitaxy processed MMIC power amplifier for Ka band wireless applications”, Third European workshop on mobile/personal satellite communications (EMPS 98).
9. F. Sepehry-Fard, “The design and fabrication of a novel ½ watt, n>52% Solid Phase Epitaxy processed MMIC power amplifier for Ka band wireless applications”, Book published by M. Ruggieri, titled “Mobile and Personal Satellite Communications 3”.
10. F. Sepehry-Fard, “Application of novel Solid Phase Epitaxy GaAs processed Low Noise Up/Sown Converter for a cost effective wireless system capable of remotely and exactly location monitoring”, International Conference on Telecommunications (ICT 98), 22-25 Jun., 1998, Chalkidiki, Greece.
11. F. Sepehry-Fard, “The st Effective Application Specific Monolithic Microwave Integrated Circuit for Broad band Wireless Applications”, International Conference on Telecommunications, Jun. 4-7 2001, Bucharest, Romania.
12. F. Sepehry-Fard, “Universal st Effective Microwave and Millimeter wave Transceiver for Broadband Wireless Applications”, International Conference on Telecommunications, Jun. 4-7 2001, Bucharest, Romania.
13. F. Sepehry-Fard, “Application of SPE Processed MMICs for the Multimedia Ka Band satellites”, International Conference on Telecommunications, July 99, Cheju, Korea.
14. F. Sepehry-Fard, “The most cost effective MMIC Technology for LMDS Applications”, International Conference on Telecommunications, July 99, Cheju, Korea.
15. F. Sepehry-Fard, “Application of SPE Processed Integrated Photo-receiver to Optical Phase Locked Loop”, International Conference on Telecommunications, 23-26 Jun., 2002, Beijing, China.
16. F. Sepehry-Fard, “Optoelectronics conversion for 60 GHz radio over fiber systems”, International Conference on Telecommunications, 23-26 Jun., 2002, Beijing, China.
17. F. Sepehry-Fard, “Application of Most Cost Effective Solid Phase Epitaxy Compound Semiconductor Fabrication Process to GaN Devices”, International Conference on Telecommunications, 3-6 May, 2005, Cape Town South Africa.

None of the prior art teaches the features of the current invention.

### SUMMARY

We teach a new and very cost effective device processing technology called Solid Phase Epitaxy (SPE) for solar cells. We have applied this technology on other devices, as well. A summary of advantages of this novel process over the competition is as follows:
Reduced processing time: Substantial reduction in wafer processing time, allowing production speeds in the range of 3 to 30 times faster than metal organic chemical vapor deposition (MOCVD) and molecular beam epitaxy (MBE) systems.
Higher source material utilization: Substantial increase in source material utilization to greater than 90%, compared with the roughly 40% utilization of MOCVD and MBE technologies.
Elimination of toxic gas inputs: SPE reactor does not use toxic gas in the epilayer growth process, making this technology safer with respect to both storage and production activity, while lowering input costs related to gas storage, delivery, exhaust, and drainage systems.

Operation at atmospheric pressure: SPE reactor operates at atmospheric pressure, eliminating the need for sophisticated and expensive vacuum systems.
Simplicity: Due to absence of vacuum systems and toxic gas in the SPE reactor, design complexity is reduced, as is the overall size of the reactor.
These benefits combine to bring down the cost of these ZnSe/GaAs/Ge solar cells significantly, compared with MOCVD and MBE depositions by a factor of at least 20.

Please note that our technology (of using ZnSe) has significant advantages over InGaP, that most (if not all) MOCVD and MBE people are using in conjunction with GaAs/Ge solar cells. For example, the band gap of GalnP/GaAs/Ge (used by Spectrolab et al) is 1.93 eV (i.e. 640 nm), its half hi wide response range is 370-650 nm (response peak is at 500 nm). It nearly completely drops into the half hi wide response range of single junction GaAs: 410-880 nm. Therefore, GalnP is not an optimum selection for high frequency band of solar spectrum. That is, GalnP blocks the GaAs to absorb photons (it absorbs some photons which should have been absorbed by GaAs). This means that substituting GalnP with ZnSe should equate to several points of percentage increase that can be added into the efficiency, due to a larger Eg (band gap) of the ZnSe, as compared with GalnP.

### BRIEF DESCRIPTION OF THE DRAWINGS

FIG. 1 shows our solid phase epitaxy reactor.

FIG. 2 shows ZnSe/GaAs/Ge solar cell energy band gap diagram, with cross sectional dimensions.

FIG. 3 shows a typical cross section of ZnSe/GaAs/Ge high efficiency concentrator solar cell.

FIG. 4 shows a typical cross section of ZnSe Solar cell.

### DETAILED DESCRIPTION OF THE PREFERRED EMBODIMENTS

We introduce GaAs/Ge solar cells that have multiple end uses. Our first focus, however, is for utility plant usage with space applications being our secondary market.

Higher efficiency and lower costs solar cells are needed to reduce solar array mass, stowed volume, and cost for Air Force (AF) space missions, and are also needed for terrestrial applications. Conventional crystalline multijunction solar cells are currently limited in efficiency by the complexity of adding more junctions to increase absorption of the solar spectrum, and the necessity to match lattice parameter and current for each junction. It is anticipated that some solar cell designs can overcome these limitations with potential for efficiencies of >60%. Incorporation of the quantum structures can create intermediate states within the band gap to harvest photons with energy less than the band gap of the host material. Quantum structures can be introduced into polymeric materials to create extremely low cost, high specific power, flexible solar cells. The inorganic, radiation-hard versions of these devices are possible. Quantum structures in these devices can be optimized to absorb a large portion of the solar spectrum.

The ideal new solar cell would be flexible and lightweight. However, efforts should be focused on significantly increased metrics (W/m2 and W/Kg) over state of the art (SOA) multijunction solar cells at lower costs. Current array level costs for space applications are ˜$1000/Watt. A threshold cost for early systems based on the new technology would be comparable or less than current systems, with costs dropping to <$250/watt with continued development. Current state-of-the-art crystalline multijunction solar cells are ˜30% efficient, >350 W/m2, and ˜70 W/Kg at the array level for space applications. Thresholds for the new technology would be >40% efficiency, >450 W/m2, and >250 W/kg for space applications. Objectives would be >60% efficiency, >700 W/m2, and >500 W/kg for space applications.

Technological hurdles are expected to include (but are not limited to): (1) synthesizing and ordering geometrically optimized structures; (2) increasing the transport and separation of photogenerated carriers; and (3) increasing environmental stability (including ultraviolet (UV) radiation, electron and proton radiation, and atomic oxygen) for space applications.

The potential for significantly increased air mass zero (AMO) conversion efficiency over SOA will enable high power platforms supporting higher bandwidth communication and high power radars for space based applications. In addition, higher power per area could enable body mounted solar cells for some spacecrafts, significantly increasing space mobility and allowing spacecraft to be built and launched faster. The potential low costs and high manufacturability of these solar cells will further remove the solar array as a cost driver, allowing for plug-and-play array solutions to be developed. System level array and integration issues should also be considered.

The target cost numbers for terrestrial applications are significantly lower, as an example, a 28% efficiency 4 inch GaAs/Ge solar cell approximately provides for 2 watts of output power, and sells, in large volumes, for $350, which equates to $175 per watt for space applications. Current poly-silicon wafers from Silicon Valley's recent public companies, such as T J Rogers' Cypress semiconductor, called Sun Power (NASDAQ-SPWR), for the 6 inch poly-Si wafer, are sold at $5, which after processing, costs them $10. At their current solar cell efficiency, this equates to at least $5 per watt. These numbers, as well as Sun Power Balance sheet, indicate that this company is losing money, based on the sales price to the consumers.

For example, one recently obtained a quotation for a 5 KW system to be installed at his house. That came out to be over $34000. With the California subsidy of $2.8 per watt, it is over $48000/system, which makes it to be a $9.6 per watt system. There is approximately 50% cost due to solar cells, which makes it about $5 per watt, which sounds right. This is another way of checking our numbers/calculations here. The target number should be less than $1 per watt. Currently, with the shortages, prices of the Si wafers have been increasing. Therefore, we are presenting another solution to the Si wafers shortages (shortage of feedstock) and costs escalation for solar cell applications.

Recently, we have been in discussions with a publicly traded company called AXT (AXTI is the symbol) that is and has been selling Ge substrates for the GaAs/Ge solar cells, for space and other terrestrial applications. They have ensured us that they would like to collaborate with us, in order to bring down the costs of their Ge substrates significantly, to a price point that can compete with Poly Si substrates which is in the $5 range for a 6 inch diameter substrate. They have indicated to us that they will undertake significant R&D to bring down the costs of their Ge substrates, and to increase their wafer sizes to 6 inches and beyond, from their current 4 inch diameter size. Typical GaAs solar cells provide for 28% efficiency vs. their Si counterpart which provides for about 17%. As an example, let's put some numbers in perspective:

One football field size of solar cells @˜17% efficiency @1 Sun provides for approximately 500 KW of power. Using MJ GaAs/Ge Solar Cells with approximately 35% (possibly with concentrators as optics, and aluminum very cheap) at concentration of 500 suns, 500 MW will be produced. Please note that GaAs solar cells can operate at much higher temperatures, and they are more rugged & reliable than Si. Thus, they are much more suitable candidates for concentrators. As a matter of fact, one of the primary reasons that GaAs was used (and has been used for space missions) is due to this fact that it is more radiation-hardened, and it can operate at much higher temperatures. The challenge to date has been its costs, as previously articulated on. The costs are primarily made of two major elements: Epitaxial costs and Ge substrate cost. Emcore claims that they sell MOCVD processed 4 inch epitaxial GaAs/Ge solar cells in very high volume (for space applications) at $350 each. This is what companies like Emcore charge their customers.

Let's look at the make-up of this cost: The Ge substrate is bought primarily from a company in Belgium at a cost of $100 per wafer for a 4 inch diameter. Emcore (a US company which specializes in MOCVD reactors) claims that their un-yielded wafer cost (meaning that there are no bad areas on the wafer, and precluding the bus bar area (meaning in a perfect environment)) (according to 1996 dollars (ref: 25^{th} IEEE Photovoltaic Specialists Conference in Washington, D.C., from May 13-17, 1996 second tutorial)) is $1.3/cm². This equates to approximately $106 for a 4 inch wafer. There is at best a 50% yield factor that needs to be accounted for, which brings the cost of the MOCVD grown GaAs/Ge solar cell to be about $212. Please note that these are 1996 dollars. (e.g. 1 Euro at that time was $0.85, approximately. Today, 1 Euro is $1.27, which means that the dollar (against Euro) has gone through a better than 50% depreciation, and it has also depreciated against other currencies.)

These facts only amplify the deficiencies in our competition products and processes, which are inherently very expensive and unfit for mass consumer applications. That is why for over three decades and in spite of hundreds of millions of dollars (if not several billions of dollars) of development expenses, it remains expensive to develop and manufacture GaAs solar cells for very low volume applications, such as in defense and space, and certainly unfit for mass consumer applications, such as solar cells for power plants.

In the next few paragraphs, we will look at why our SPE is at least 20× cheaper than MOCVD and MBE, which makes our equivalent epitaxial material to be at most at about $10, for a 4 inch epitaxial material, minus the Ge substrate, which we will address later on.

At 28% efficiency, this equates to over 2 Watts of power per 4 inch wafer, which equate to $5 per watt, minus the Ge substrate cost (e.g. minus the Ge substrate cost, which today, we are at par with poly Si companies). This takes into account the worst case scenario (e.g. 20× cheaper than the competition. With the economy of scale, robotics, automation, and increasing the size of the source and substrates, we will be approaching our target of under $1 per watt, including Ge substrates and processed material).

In reality, we are between 30× to 40× cheaper than MOCVD and MBE. Here is why: Our growth rate is 3 to 30× faster (typical MOCVD growth rate is 4 micron per hour, and in the case of MBE, it is only 1 micron per hour. SPE's growth rates are 0.2 to 2 micron per minute). SPE does not utilize very expensive vacuum systems unlike its competition. SPE does not utilize Arsine and Phosphine.

Typically, MOCVD's source material utilization is 40%, but SPE consistently uses over 90% of its source material. Price of a MBE system is over $3.5 million, but a fully automated SPE will not cost more than 10% of MBE, namely $350000. Due to very dangerous, expensive chemicals used in the MOCVD and MBE, there are direct and indirect costs, such as very expensive locking mechanisms, leak detectors, high insurance costs, due to leakage of dangerous gases, inherent in conventional processes that we do not need to worry about, when using SPE.

Our new Solid Phase Epitaxy technology and the GaAs/Ge solar cells create an opportunity to either replace old, inefficient, and unreliable solar cells for military, commercial satellites, and in particular terrestrial utility plant applications, with form-fit replacements, or to create new solar cells, which replace several of these solar cells for next generation upgrade capability. Despite considerable engineering effort and numerous redesigns, development of low cost solar cells for military, commercial applications has been hindered from fundamental device and application perspectives. Polycrystalline and mono-crystalline Si solar cells are very difficult devices to provide for adequate power, reliability, temperature handling capability with adequate efficiency, and radiation hardness, that is required for space missions, due to flares, atomic oxygen, and hostile high energy particles emanation, such as lasers to satellites, thereby killing the exposed cells, hence disabling the military/commercial satellites, by terrorists or hostile governments to our country.

This is in part due to inherent smaller band gap as compared to GaAs, 0.7 eV vs. 1.43 eV. GaAs solar cells are inherently much more efficient, radiation hardened, and can operate at much higher temperatures. GaAs solar cells are inherently more efficient than Si Solar cells, which means requiring additional mass for Si, as more Si solar cells are required to provide for the same amount of power, compared to GaAs solar cells. This will translate to 3 to 5× life expectancy for GaAs solar cells vs. Si solar cells, which means increasing the lifetime of a satellite by a factor of 3 to 5× (although there are other life limited items on the satellites such as jet fuels, etc, with the advent of ion beams, replacing jets as engines for satellite, the life expectancy should be significantly improved).

In addition, manned space missions must operate below the intense radiation belts (low earth orbits), because of limited shielding available. At these low orbits, atmospheric drag can cause the satellite orbit to degrade. This in turn requires the addition of additional rocket fuel to maintain the required orbit. Low array areas can reduce the drag, and one option being explored to minimize drag is the use of higher efficiency arrays such as our invention/product ZnSe/GaAs/Ge solar cells.

Furthermore, additional area and mass will mean more drag on the spacecraft. More drag on the spacecraft subsequently means more jet fuels consumption (e.g. in the case of Si solar cells) for positioning the satellite and maintaining its orbit, relative to earth (e.g. geosynchronous, polar, LEO, MEO, etc.), and also which equates to more weight during launch of the satellite (e.g. presently, there is a cost of approximately $5000/Kg for launching satellites). There are several Life Limiting Items (LLI) on a spacecraft, and solar cells are among them. For some of the maintainable missions, such as space station freedom alpha (SSF), the removal and repair of solar cells in space is costly. Most of the current satellites have been designed to be a “one-shot” mission, and hence, non-repairable, therefore, huge accent has been put on very highly reliable components (components that can take the very stringent requirements of the space, due to various reasons such as cosmic rays, solar flares, atomic oxygen, and other phenomenon, such as single event upsets) (most of the potential problems for digital devices in space are in the areas such as flip flops, etc., where the state (e.g. 0 or 1) of the digital device will be ruined, due to some of these high energy particles).

Some satellites are designed to be repaired in space, thanks to the space station freedom alpha. Also, in this case, longer lifetime and more efficient solar cells will have a much better return on investment for the owners of this investment.

We have demonstrated/invented a new, high efficiency GaAs/Ge solar cells, using our novel most cost effective epitaxial processing technology in the world, called Solid Phase Epitaxy (SPE).

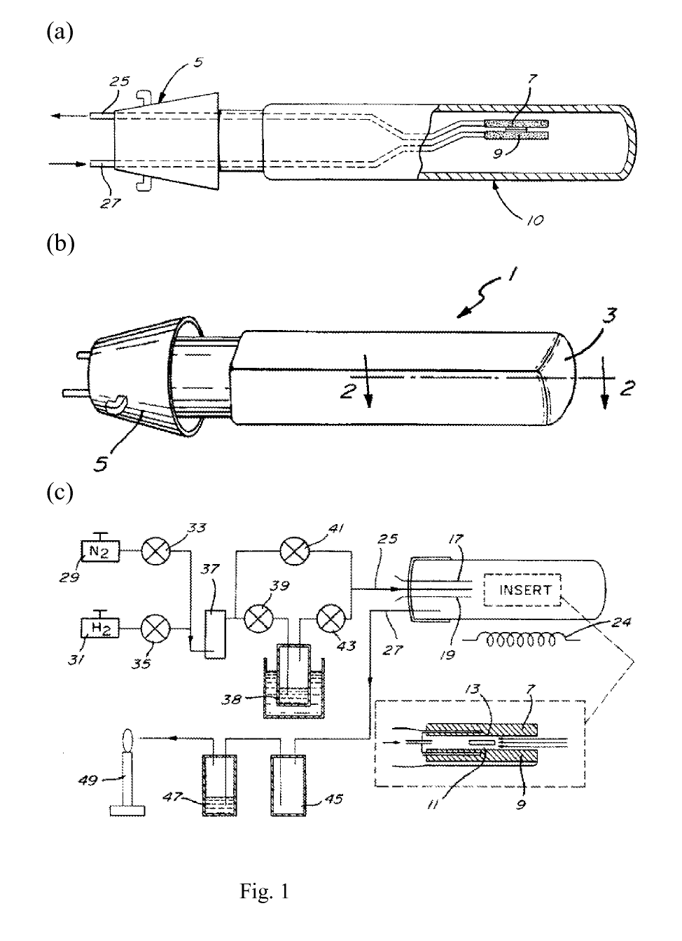

Our solid phase epitaxy reactor is illustrated in FIG. 1, which is the lowest cost deposition technology for growing layers of semiconductor material, and includes a reaction chamber, means for mounting a substrate wafer, and a source wafer in the reaction chamber. The substrate wafer and the source wafer are maintained at a predetermined distance, which is less than the mean free path of the reacting species of the semiconductor material. A heater for heating the wafers maintains a temperature difference of 20 C to 40 C between the wafers. The transporting gas reacts with the source and substrate materials, producing volatile compounds, which establish equilibrium partial pressures on those surfaces. As the source and substrate are at different temperatures, a concentration gradient of the reaction products appears, giving rise to a gas diffusion flux towards the surface with lower partial pressure. Then, the reaction direction is reversed, producing the deposition of material on the substrate surface. A characteristics of the III-V and II-VI compounds is the presence of one or more elements processing a high elemental vapor pressure. Elements, such as P, As, and Sb, as well as metals like Hg and Zn, all possess appreciable vapor pressures at typical growth temperatures. Thermal equilibrium between a solid and a gas phase environment requires both the metal and anion of the compound to be present in the vapor phase.

FIG. 1 illustrates the reaction chamber 1, which is preferably made of a fused silicon material, has a sealed end, denoted by 3, and is closed at the other end with a tapered joint, denoted by 5. As seen in the FIG. 1, disposed inside the reaction chamber are a top graphite block 7 and a bottom graphite block 9. The material of the source wafer can be selected from the following: GaAs, CdTe, HgCdTe, ZnSe, Si, Pb1-xGdxTe, AlGaAs, InGaAs, InGaAs, and GaP. The material of the substrate may be selected by the following: GaAs, GaP, Ge, Si, and KBr. The reaction chamber has a rectangular cross section. A rectangular tube is used instead of standard circular tube for the main body to obtain a maximum temperature uniformity inside the reaction chamber. The inside assembly is made of a heavy walled tube denoted by 10. A source wafer is supported on the graphite block denoted by 9, and a substrate wafer denoted by 13 underlies the graphite block 7.

Spacers denoted by 15 are disposed between the wafers located at 11 and 15. The spacers may be made of a fused silica or graphite material. Block 19 (that is the source wafer) being kept at a higher temperature. These means may comprise three glowbar (SiC) elements. The temperatures of the graphite blocks are monitored by the thermocouples. The tapered joint of the reaction chamber includes a gas inlet denoted by 27 and outlet denoted by 25. The gas inlet may be formed by using 4×6 mm tubing, and gas inserted into the reaction chamber through the gas inlet tube is brought to graphite blocks, where the gases are permitted to flow between the blocks. The gas outlet may comprise a 4×6 mm tube, extending from the tapered joint to the exterior.

Our Very High Efficiency, Low Cost SPE, to be Applied to Thin Film ZnSe/GaAs/Ge Heteroepitaxial Solar Cell Structure:

We use our SPE method on a very low cost very high efficiency heterostructure ZnSe/GaAs/Ge solar cells, to reduce solar array mass, stowed volume, and cost for space missions and terrestrial utility plant applications. In this system, the known high photovoltaic power conversion efficiency of GaAs is combined with the lower cost and availability of large surface area germanium single crystal substrate material, along with the beneficial properties of ZnSe, as window material and frequency down converter. Due to significantly good lattice matching of the three crystals, the heteroepitaxy of ZnSe/GaAs as well as the GaAs/Ge can be realized.

GaAs solar cells have distinct advantage over Silicon, due to their higher efficiency, radiation hardness in space applications, and greater survivability in higher temperatures. The band gap of ZnSe of 2.67 eV makes its application as window material evident. However, two more advantages characteristics can be highlighted: the first is the probability of the formation of the quaternary compound GaₓZn_{y}As₁₋ₓSe_{1-y}, due to inter diffusion of the two layers during deposition. This gives rise to the creation of a graded energy gap at the interface, resulting in a built-in field, close to the active shallow junction in GaAs. In addition, a multicolor integrated absorption could increase the collection efficiency. Secondly, the existing luminescence level of ZnSe acts as a frequency down converter, enhancing the efficiency of GaAs active material.

GaAs on Ge, with ZnSe as the window material:

Due to higher power conversion efficiency, greater survivability at higher temperatures, permitting large scale sun energy concentration, and its radiation hardness, the GaAs cells have a definite advantage for terrestrial and space applications over Silicon solar cells. Recent developments in fabrication technology have demonstrated the feasibility of high yield mass production of GaAs solar cells. The application of Ga₁₋ₓAlₓAs in combination with GaAs, Si and/or Ge solar cell, to realize an integrated structure with conversion efficiency >60%, will be achieved with our structure and SPE growth reactor.

In this work, we make heteroepitaxial structure of ZnSe/GaAs/Ge solar cells. In this solar cell structure, the high photovoltaic power conversion efficiency of GaAs is enhanced by the ZnSe window material, and by the formation of a graded band gap GaₓZn_{y}As₁₋ₓSe_{1-y} quaternary compound, at the heteroepitaxial interface. This band structure with its inherent built-in potential, lying close to the shallow p-n junction in the GaAs, increases the collection efficiency of the generated and separated carriers. In addition, the spectral response of the graded gap system is extended, covering the two band gaps between the two band gaps: 1.43 eV at the GaAs side and the 2.67 eV at the ZnSe side of the quaternary interfacial compound. Finally, the existing luminescence level, lying 0.5 eV below the conduction band edge of ZnSe, acts as a frequency down converter. Consequently, some of the high energy part of the solar radiation is transformed to a lower frequency, closer to the one given by the band gap of GaAs, the active part of the heteroepitaxial structure. In some publications and development work, we see utilization of GaAlAs as windows, which requires large amounts of Al, that leads to difficulties in forming ohmic contacts to the window. Furthermore, since AlAs is hygroscopic, their contacts may deteriorate, when exposed to the air during assembly, other ground based operations, or during flight mission. Additionally, deterioration of the window layer may lead to extraneous photon absorption, which will reduce the light generated output. Therefore, the use of ZnSe as window can be seen as an excellent alternative to the above mentioned problems. The large direct band gap of ZnSe permits the collection of the high frequency part of the solar radiation. In addition, ZnSe known luminescence can be used as a frequency down converter to enhance the conversion efficiency of the p-n junction of the active GaAs. Furthermore, ZnSe, as window material, decreases surface recombination losses, and the possible formation of a quaternary GaZnAsSe graded band structure could improve the collection efficiency, due to an induced electric field near to the shallow junction in GaAs.

Germanium is chosen as the substrate material of the thin film system, due to its satisfactory lattice matching with the epitaxial layers of GaAs and ZnSe. Germanium is the material of the easiest to prepare in single crystal, especially with large dimensions. Its availability as large area single crystal is a major cost reducing component in this heteroepitaxial structure. In addition, there is an excellent lattice matching between the two crystals (only ˜0.2% difference).

The Energy Integrator Solar Cell:

To exploit a larger part of the solar energy spectrum, peaking at around 2 eV, different combinations of Ge—Si—GaAs—AlAs systems are considered. The cell constructions are based on the satisfactory lattice matching of the materials with appropriate energy gaps. Some examples are collected in table 1.

TABLE 1
Relevant physical properties of some materials used for solar cells.

| | Energy Gap | Lattice const. | |
|---|---|---|---|
| Material | (eV) | (nm) | Gap Trans. |
| Ge | 0.66 | 0.5658 | indirect |
| Si | 1.11 | 0.5431 | indirect |
| GaAs | 1.43 | 0.5654 | direct |
| AlAs | 2.15 | 0.5661 | indirect |
| ZnSe | 2.67 | 0.5667 | direct |

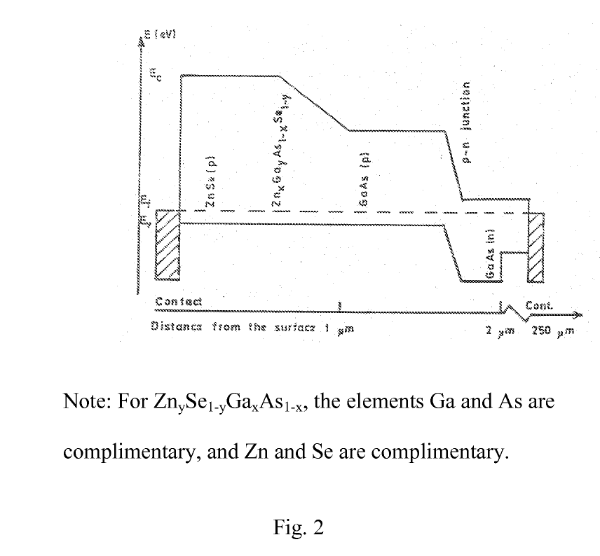

It can be seen that Si, due to its lattice constant, is not readily incorporable into a heteroepitaxial system. The often used AlAs as a ternary compound with GaAs is disadvantaged, with respect to ZnSe, due to its lower and indirect band gap. Therefore, ZnSe with its direct and larger gap will be used here. The energy spectrum extension is related, as in the case of GaAlAs, to the possible formation of a quaternary compound, ZnₓGa_{y}Se₁₋ₓAs_{1-y}. Since, in this case, both ZnSe and GaAs are direct band gap materials, the resulting sharp absorption edges of their layers permit the usage of thin films for effective sun energy absorption. Due to the formation of the above mentioned quaternary compound, the spectral response of the solar cell is expected to be extended to the high energy side of the solar spectrum, with respect to the one related to the lower band gap of AlAs in the ternary system. In addition, a built-in field, caused by the graded band structure, increases the collection efficiency of the separated electron hole pairs by the p-n junction in the active part of the cell, which is GaAs. Finally, ZnSe has a so-called self-activated luminescence level of 0.5 eV below the conduction band edge which transforms some of the high energy part of the solar radiation to lower frequencies, closer to the absorption edge of the active GaAs. Furthermore, it has been found that the resistivity of the large band gap ZnSe, more than 10⁶ ohm cm, dramatically decreases, to about 2×10⁻¹ ohm cm, if the substrate material is GaAs. The measured hole concentration, in this case, is 8×10¹⁷ cm⁻³, and the carrier mobility is 37 cm⁻¹ volt⁻¹sec⁻¹. This data strongly indicates the formation of the quaternary compound of ZnₓGa_{y}Se₁₋ₓAs_{1-y} introduced in this investigation. Consequently, the resulting decreased series resistance of the cell represents an additional advantage of this system. The basic structure of the heteroepitaxial energy integrator cell is shown schematically in FIG. 2.

Here, E_{c} represents the conduction band edge, E_{f} is the Fermi level, Eᵥ indicates the position of the valence band, and the distance is measured perpendicular to the surface of the cell. The top ZnSe layer will be deposited by SPE technique. The source of ZnSe will be maintained at 850° C., the GaAs will be deposited epitaxially on the germanium substrate, at about 650° C. The reaction tube is made of fused silica, and the temperatures will be realized by a two zone furnace. The deposition rate, using a hydrogen gas flow of 200 ml/min, should be about 0.2 um per hour. The crystal structure of the ZnSe will be verified by x-ray measurements.

The GaAs active layers are deposited prior to the deposition of ZnSe epitaxial films. Two systems are accomplished here: one is the classical AsCl₃—H₂—Ga set up, using HCl as transport agent. In this system the germanium substrate is maintained at 750° C., and the Gallium source is at 850° C.; the hydrogen gas flow through the appropriate AsCl₃ saturators are 500 ml/min. The fused silica reaction chamber will be heated by a two zone Kanthal furnace. In the second system, in solid phase epitaxy transport reaction, wet (at 0° C.) hydrogen is used as the transport agent of the GaAs source material, separated by a spacing of 10 to 50 um from the single crystal germanium substrate. A temperature difference of 10 to 50° C. is maintained between the source and substrate wafers, to carry out the transport reaction at temperatures of 750 to 850° C. The major advantage of this system lies in its simplicity and easy applicability to large surface area deposition, needed for industrial solar cell fabrications.

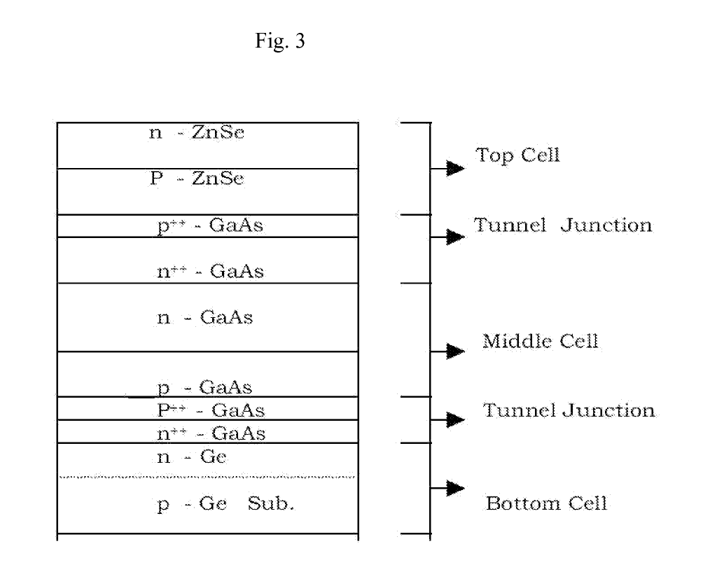

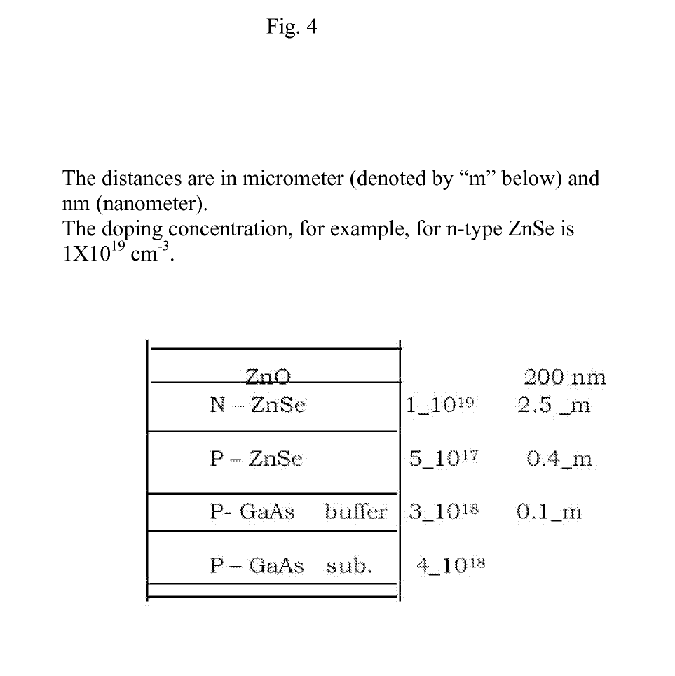

As an example, FIG. 2 shows ZnSe/GaAs/Ge solar cell energy band gap diagram, with cross sectional dimensions. FIG. 3 shows a typical cross section of ZnSe/GaAs/Ge high efficiency concentrator solar cell. FIG. 4 shows a typical cross section of ZnSe Solar cell.

Thus, in summary, an energy integrator solar cell system is presented. The heteroepitaxial structure of ZnSe/GaAs/Ge is realizable, due to the adequate lattice matching of the component crystals. It offers several advantages compared to the other solar cell systems based on AlₓGa₁₋ₓAs/GaAs/Ge/Si type of heteroepitaxial photovoltaic solar energy converters. The active p-n junction is maintained in the well-known high power conversion efficiency of GaAs. ZnSe is a direct large band gap semiconductor. Therefore, the energy integration effect of the graded band structure of the type ZnₓGa_{y}Se₁₋ₓAs_{1-y}, created at the heteroepitaxial interface, is extended, with respect to the one present in the GaₓAl₁₋ₓAs system. This graded band gap phenomenon introduces a built-in potential, improving the capture efficiency of the GaAs p-n junction, placed to its close vicinity. Furthermore, the luminescence of ZnSe, acting as a frequency down conversion path, increases the spectral response of the solar cell system. Using germanium as an available large substrate material, the thin film ZnSe/GaAs/Ge heteroepitaxial structure could result in a much high power conversion efficiency, and a reduced cost for the solar energy converter.

The structure introduced here for the solar cell is a novel one. The SPE applied to this structure is also a novel method. Although, any other growth method, such as MBE, MOCVD, MOMBE, mixed-technique, or mixed-source, such as solid, liquid, or gas, can also be used to grow the solar cell, and their applications to this structure would still be novel.

In addition, in one embodiment, some layers may be grown by a first method, and other layers by another second method (potentially, may or may not be in another machine) for optimization of the growth, speed of process, uniformity, or for pure economic reasons.

There is also an embodiment for growing two layers (or more layers, substrate, or thinned substrate/layer), and sandwich them, or stack them on top of each other, mechanically, instead of real crystal growth.

In one embodiment, the compound used has 4 elements, such as ZnGaAsSe. While, in other embodiments, it has 2, 3, or 5 elements (or more than 5 elements). In one embodiment, the semiconductor is pseudomorphic, mismatched lattice-wise, and/or metamorphic. In one embodiment, ZnSe is used as the top layer or window. In one embodiment, an anti-reflective coating (AR) is used on the top layer, to reduce surface recombination. In one embodiment, tunnel junctions are used between the layers. In one embodiment, the doping profiles are chosen for a higher tunneling effect.

In one embodiment, multiple layers, multiple cells, or subcells are used. In one embodiment, multiple layers, multiple cells, or subcells are used with different gradings (for either dopants or mole fraction, or both), band gaps, or dopings, to change the band gap structure and size, or to change energy levels (for example, for E_{c} and Eᵥ), in order to absorb the electromagnetic radiation at different or multiple wavelengths or energies, corresponding to Sun or other sources of radiation, to maximize/optimize absorption, conversion to electricity, and/or efficiency, depending on the weather condition, cloudiness, air quality, season, geographical location, spectrum, the characteristic curve/wavelengths, atmospheric absorption/composition, solar activity, and peak energies.

In one embodiment, the change of composition or doping is done abruptly, while in another embodiment, it is done gradually, or graded/ramped. In one embodiment, the substrate or layers are GaAs, Ge, InP (for example), or any other semiconductor (for example, Si, Ge, III-V or II-VI alloys/compounds), metallic, or any non-semiconductor material/substrate, with crystalline, polycrystalline, pseudomorphic, strained, non-strained, or amorphous structure, with or without dopants, or unintentionally doped. In one embodiment, the layers, substrate, or structure is thinned for lower weight or mass for space applications. In one embodiment, the grown material are thinned or removed from the substrate, and the structure is put on or mounted on a new substrate, which may or may not be the same material.

In one embodiment, there is a buffer. The buffer can have same or close lattice constant. The buffer can have different lattice constant. The buffer can be amorphous, strained, supperlattice, graded, low-temperature grown, or pseudomorphic. In one embodiment, the contacts are at the front and back of the substrate. In one embodiment, there are multiple, parallel, or finger-shaped contacts. In one embodiment, both contacts are at the same side of the substrate, with the optional connection done through substrate or from the side of the substrate, such as on the edge of the substrate, or through a hole in the substrate. In one embodiment, the layer is capped. In one embodiment, the contact is ohmic contact. In one embodiment, it is a non-ohmic contact.

In one embodiment, the system has at least a concentrator for focusing the light. In one embodiment, it is a monolithic structure. In one embodiment, it is a continuous growth procedure. In one embodiment, it is a multiple growth procedure, with or without delay in-between, in one or more chambers or equipment, with one or more techniques, methods, or technologies. In one embodiment, it covers or absorbs more than one wavelength or a range of energies. In one embodiment, it is a tandem solar photovoltaic converter.

In one embodiment, it is used for on-Earth applications, while in another embodiment, it is used for space applications. In one embodiment, the thickness of layer or sublayer is set according to absorptivity of a layer (absorption cross section), with respect to a wavelength or energy range. In one embodiment, it is optimized for current, voltage, or power, for example, by band gap engineering. In one embodiment, it (i.e. the solar cell structure) has a middle cell window. In one embodiment, it has a nucleation layer. In one embodiment, the substrate is 2″, 3″, 4″, or more/less, in diameter. In one embodiment, the electrical conductivity of the layer(s) is graded/ramped. In one embodiment, the quantum efficiency is optimized, for example, by choosing the right material/compound/structure.

In one embodiment, there are 3 (main/primary) layers/subcells: top, middle, and bottom. In one embodiment, the contact resistance is lowered, by adjusting/setting the doping and contact metal(s). In one embodiment, the top layer can also act as a frequency down-converter, using its luminescence property. The optional transition region/layer between the first and second layers (top and middle subcells) has a built-in potential. In one embodiment, the layer between the main layers is a PN-junction.

In one embodiment, the lattice constant of the 3 main layers are substantially the same. In one embodiment, the percentage of lattice difference is 0.001, 0.01, 0.1, 1, 2, 5, or 10 percent. In one embodiment, the material is amorphous, semi-amorphous, metamorphic, mismatched, strained, full of defects and dislocations, or pseudomorphic.

In one embodiment, we have for energy gaps (E_{g}):

E_{gTop}>E_{gMiddle}>E_{gBottom}

In one embodiment, one or more band gaps are direct. In one embodiment, one or more band gaps are indirect. In one embodiment, the system can be set/programmable based on city and weather condition (programmable wavelength shifting or adjusting). In one embodiment, the current matching is substantially achieved, based on thicknesses and absorptivity of the layers (for the serial connection of the subcells, for example). In one embodiment, back surface reflector is used.

In one embodiment, current matching is not required, due to the parallel conduction of the layers (rather than serial connection of the subcells), using parallel contacts directly on each layer, for example, by etching or producing steps on each layer, to be able to reach each layer directly to put contact/metallization. Then, the sub-currents are aggregated or combined at a later stage/location, on-wafer or off-wafer/substrate.

In one embodiment, the PN junction is of high efficiency. In one embodiment, the radiation degradation is low, due to structure design, the layers, and the material used for the layers. In one embodiment, superlattices or periodic structures are used in buffer, layers, transition layers between main layers, or near the cap or contacts. In one embodiment, the layers or surfaces are treated by chemicals for surface recombination, metallization, preparation of substrate, or defects. In one embodiment, thin layers or tunneling structures/barriers are used in (or between) main layers. In one embodiment, the alloys, metallization, contacts, substrates, or semiconductors with good thermal conductivity are used. In one embodiment, the material is radiation hardened. In one embodiment, the material is monocrystalline or polycrystalline. In one embodiment, the device is shielded against some cosmic radiations. In one embodiment, a bifacial, zero-axis, large angle, or small off-axis substrate is used.

In one embodiment, metal bonding is used. In one embodiment, the visible or invisible lights/radiation is absorbed. In one embodiment, a handle material is used, in combination with conductive epoxy, for example. In one embodiment, SI, non-intentionally doped, ion-implanted, or background doping is used for substrate or layers. In one embodiment, the shape of the substrate is oval, square, triangle, rectangle, circular, or other geometrical shapes.

We have used phrases “photovoltaic converter/cell” or “solar cell/converter” (or apparatus/device/system) to mean and cover all of the devices/systems in that class.

Any variations of the teachings above are also intended to be covered by the patent protection for the current application.

1. A multi-layer photovoltaic apparatus, wherein said apparatus comprises:
a first layer;
a second layer;
a third layer;
a first contact connected to said first layer; and
a second contact connected to said third layer,
wherein said first layer absorbs some of a radiation energy,
wherein said second layer absorbs some of said radiation energy,
wherein said third layer absorbs some of said radiation energy,
wherein said apparatus converts some of said radiation energy to electrical current, potential, or energy.

2. An apparatus as recited in claim 1, wherein the source of said radiation energy is from one or more of the followings: the Sun, the Moon, volcano, man-made light source, a natural phenomenon, visible radiation, invisible radiation, electromagnetic wave, infrared source, ultraviolet, laser, X-ray, diode, light bulb, cosmic radiation, any part of the spectrum of the radiation in the Universe, or any radiation before passing through the Earth's atmosphere.

3. An apparatus as recited in claim 1, wherein said first layer is on top of a substrate, and said third layer is at the bottom of said substrate.

4. An apparatus as recited in claim 1, wherein said apparatus is monolithic.

5. An apparatus as recited in claim 1, wherein said apparatus has multiple band gaps.

6. An apparatus as recited in claim 1, wherein said apparatus has more than 3 layers.

7. An apparatus as recited in claim 1, wherein said apparatus's structure is exactly lattice matched.

8. An apparatus as recited in claim 1, wherein said apparatus's structure is substantially lattice matched.

9. An apparatus as recited in claim 1, wherein said apparatus's structure is lattice mismatched.

10. An apparatus as recited in claim 1, wherein said apparatus's structure is metamorphic, strained, amorphous, polycrystalline, monocrystalline, or pseudomorphic.

11. An apparatus as recited in claim 1, wherein said first layer's band gap is larger than said second layer's band gap, and said second layer's band gap is larger than said third layer's band gap.

12. An apparatus as recited in claim 1, wherein the subcells within said apparatus are substantially or exactly current-matched.

13. An apparatus as recited in claim 1, wherein the subcells within said apparatus are not current-matched.

14. An apparatus as recited in claim 1, wherein the current from the subcells are in series.

15. An apparatus as recited in claim 1, wherein the current from the subcells are in parallel.

16. An apparatus as recited in claim 1, wherein said first contact and said second contact are in the opposite sides of the substrate.

17. An apparatus as recited in claim 1, wherein said first contact and said second contact are in the same side of the substrate.

18. An apparatus as recited in claim 1, wherein one or more of said first contact or said second contact are at the edge side of the substrate.

19. An apparatus as recited in claim 1, wherein said first contact and said second contact are ohmic contacts.

20. An apparatus as recited in claim 1, wherein said apparatus comprises quantum dots.

21. An apparatus as recited in claim 1, wherein said apparatus comprises the substrate.

22. An apparatus as recited in claim 1, wherein said apparatus is on the substrate.

23. An apparatus as recited in claim 1, wherein said apparatus comprises epitaxially grown material.

24. An apparatus as recited in claim 1, wherein said apparatus is grown by MBE, MOCVD, gas source, solid source, liquid source, or a combination of different techniques.

25. An apparatus as recited in claim 1, wherein the layers of said apparatus is grown in one or more chambers or growth systems, sequentially.

26. An apparatus as recited in claim 1, wherein said apparatus is grown continuously as one piece.

27. An apparatus as recited in claim 1, wherein the pieces of said apparatus are grown separately, and said pieces of said apparatus are later stacked on top of each other, or are sandwiched between each other, mechanically.

28. An apparatus as recited in claim 1, wherein the substrate of said apparatus is in the shape of oval, square, triangle, rectangle, circular, or other geometrical shapes.

29. An apparatus as recited in claim 1, wherein said apparatus comprises one or more tunnel junctions.

30. An apparatus as recited in claim 1, wherein said apparatus comprises a self-aligned structure.

31. An apparatus as recited in claim 1, wherein said apparatus comprises a tunnel barrier.

32. An apparatus as recited in claim 1, wherein said apparatus comprises a structure with the lowest effective band gap being located closest to the substrate.

33. An apparatus as recited in claim 1, wherein said apparatus comprises a passivated surface.

34. An apparatus as recited in claim 1, wherein said apparatus comprises layers in tandem.

35. An apparatus as recited in claim 1, wherein said apparatus is grown by solid phase epitaxy method.

36. An apparatus as recited in claim 1, wherein said apparatus comprises high efficient subcells.

37. An apparatus as recited in claim 1, wherein said apparatus comprises radiation-hardened material or structure.

38. An apparatus as recited in claim 1, wherein said apparatus comprises ZnSe or ZnSe-based material.

39. An apparatus as recited in claim 1, wherein said apparatus is used in space.

40. An apparatus as recited in claim 1, wherein said apparatus is used in a terrestrial application.

41. An apparatus as recited in claim 1, wherein said apparatus is used in an array.

42. An apparatus as recited in claim 1, wherein the substrate of said apparatus is one or more of the followings: polycrystalline, crystalline, amorphous, on-axis, off-axis, a few degrees off-axis, doped, undoped, semi-insulating, ion-implanted, annealed material, with background doping, with un-intentional doping, with surface states, with defects, smooth surface, rough surface, or a multiple-layered structure.

43. An apparatus as recited in claim 1, wherein said apparatus is used in solar panels.

44. An apparatus as recited in claim 1, wherein said apparatus is used for the generation of electricity.

45. An apparatus as recited in claim 1, wherein said apparatus operates at high temperatures.

46. An apparatus as recited in claim 1, wherein the substrate of said apparatus comprises one or more of the following: Ge, GaAs, ZnSe, Si, InP, GalnAs, any other semiconductor, a compound semiconductor, a metal, an alloy, or a mixture or a combination of those.

47. An apparatus as recited in claim 1, wherein said apparatus has a large life-expectancy.

48. An apparatus as recited in claim 1, wherein said apparatus comprises ZnSe, GaAs, and Ge layers.

49. An apparatus as recited in claim 1, wherein said apparatus comprises a thinned substrate or structure.

50. An apparatus as recited in claim 1, wherein said apparatus comprises graded band gap.

51. An apparatus as recited in claim 1, wherein said apparatus comprises graded doping profile.

52. An apparatus as recited in claim 1, wherein said apparatus comprises a quaternary semiconductor compound as a transition layer between two main layers.

53. An apparatus as recited in claim 1, wherein said apparatus comprises a ternary semiconductor compound as a transition layer between two main layers.

54. An apparatus as recited in claim 1, wherein said apparatus comprises a built-in potential.

55. An apparatus as recited in claim 1, wherein said apparatus comprises a luminescence level.

56. An apparatus as recited in claim 1, wherein said apparatus comprises a frequency down-converter.

57. An apparatus as recited in claim 1, wherein ZnSe is used as a window material.

58. An apparatus as recited in claim 1, wherein the surface recombination losses are reduced.

59. An apparatus as recited in claim 1, wherein said apparatus comprises a direct band gap.

60. An apparatus as recited in claim 1, wherein said apparatus comprises an indirect band gap.

61. An apparatus as recited in claim 1, wherein said first contact and said second contact have low resistivity.

62. An apparatus as recited in claim 1, wherein said apparatus comprises an antireflective coating.

63. An apparatus as recited in claim 1, wherein said apparatus absorbs energy at different frequencies or wavelengths.

64. An apparatus as recited in claim 1, wherein said apparatus is optimized based on thickness, doping profiles, mole fraction, or absorptivity of each layer.

65. An apparatus as recited in claim 1, wherein said apparatus is optimized based on weather condition, cloudiness, air quality, season, geographical location, atmospheric absorption, solar activities, spectrum composition, sun or light intensity, or peak energies.

66. An apparatus as recited in claim 1, wherein said apparatus comprises one or more abrupt band gap changes.

67. An apparatus as recited in claim 1, wherein said apparatus comprises one or more abrupt doping profile changes.

68. An apparatus as recited in claim 1, wherein said apparatus comprises a buffer.

69. An apparatus as recited in claim 1, wherein said apparatus comprises a superlattice.

70. An apparatus as recited in claim 1, wherein said apparatus comprises multiple contacts to a layer.

71. An apparatus as recited in claim 1, wherein the substrate of said apparatus comprises a hole.

72. An apparatus as recited in claim 1, wherein said apparatus comprises a capped layer.

73. An apparatus as recited in claim 1, wherein said apparatus comprises a non-ohmic contact.

74. An apparatus as recited in claim 1, wherein said apparatus comprises or is associated with a concentrator.

75. An apparatus as recited in claim 1, wherein said apparatus comprises means for focusing the light.

76. An apparatus as recited in claim 1, wherein said apparatus is optimized for output power.

77. An apparatus as recited in claim 1, wherein said apparatus is optimized for output current.

78. An apparatus as recited in claim 1, wherein said apparatus is optimized for output voltage.

79. An apparatus as recited in claim 1, wherein said apparatus comprises a middle cell window.

80. An apparatus as recited in claim 1, wherein said apparatus comprises a nucleation layer.

81. An apparatus as recited in claim 1, wherein the size of the substrate for said apparatus is 2″, 3″, 4″, more than 4″, or less than 4″, in diameter.

82. An apparatus as recited in claim 1, wherein the quantum efficiency is optimized.

83. An apparatus as recited in claim 1, wherein said apparatus comprises a PN junction.

84. An apparatus as recited in claim 1, wherein said apparatus is set or programmed based on the city, location, sun intensity, or weather condition.

85. An apparatus as recited in claim 1, wherein said apparatus comprises a back surface reflector.

86. An apparatus as recited in claim 1, wherein said apparatus comprises multiple step structure on its surface for contact metallization for different layers.

87. An apparatus as recited in claim 1, wherein currents are aggregated from different layers or contacts.

88. An apparatus as recited in claim 1, wherein the surface is treated by chemicals or gasses.

89. An apparatus as recited in claim 1, wherein said apparatus comprises one or more layers with good thermal conductivity.

90. An apparatus as recited in claim 1, wherein said apparatus comprises a metal bonding.

91. An apparatus as recited in claim 1, wherein said apparatus comprises a handle material, in combination with conductive epoxy.
